(19) United States
(12) Patent Application Publication
(10) Pub. No.: US 2015/0325441 A1
(43) Pub. Date: Nov. 12, 2015

(54) SEMICONDUCTOR FABRICATION METHOD

(71) Applicant: Powerchip Technology Corporation, Hsinchu (TW)

(72) Inventors: Hsin Tai, Hsinchu City (TW); Yu-Mei Liao, Hsinchu County (TW); Wei-Ting Liu, New Taipei City (TW); Wen-Chuan Peng, Hsinchu County (TW)

(21) Appl. No.: 14/510,120

(22) Filed: Oct. 9, 2014

(30) Foreign Application Priority Data
May 9, 2014 (TW) 103116569

(51) Int. Cl. H01L 21/033; H01L 21/311

(52) U.S. Cl. CPC H01L 21/0337; H01L 21/31144

(57) ABSTRACT

A semiconductor fabrication method is provided. A substrate having thereon a base layer, a hard mask layer, and a core layer is prepared. A resist pattern is transferred to the core layer, thereby forming a core pattern. The core pattern is subjected to a post-clean process. Thereafter, a spacer layer is deposited on the core pattern. The spacer layer is etched to form spacer pattern on each sidewall of the core pattern. The core pattern is then removed. The spacer pattern is transferred to the underlying hard mask layer and the base layer.

### CROSS REFERENCE TO RELATED APPLICATION

This application claims the benefit of Taiwan patent application No. 103116569, filed on May 9, 2014, the disclosure of which is incorporated herein in its entirety by reference.

### BACKGROUND OF THE INVENTION

1. Field of the Invention

The present invention relates to a semiconductor process. In particular, the present invention relates to a self-aligned double patterning (SADP) process.

2. Description of the Prior Art

As known in the art, a photolithographic process including the steps of exposure and development is typically used to transfer a circuit pattern from a mask to a wafer. With the trend towards scaling down the semiconductor products, the conventional photolithographic technologies face formidable challenges. For the mainstream ArF excimer laser photolithography (wavelength: 193 nm), the reachable minimum half-pitch of a transistor device produced by this kind of light source during exposure in the photolithographic process is 65 nm. By incorporating the well-known immersion lithography technology, the reachable half-pitch may be further reduced to 45 nm.

To use existing equipment to fabricate the fine line circuit beyond the exposure limits, the industry has developed a self-aligned double patterning (SADP) technology, which includes hard mask stack, core deposition, followed by lithography exposure. The spacing and critical dimension (CD) is still loose at his stage. Then, the resist is trimmed to the CD, and then the pattern is transferred from photoresist to the core layer by dry etching. A spacer layer is then deposited and then etched. The core layer is then removed. Finally, the spacer pattern is transferred to hard mask stack.

However, these previous techniques still have drawbacks that need improvement. For example, to obtain a more dense spacer layer to improve pattern transfer accuracy, it is necessary to adopt higher temperatures (e.g., greater than 400° C.) chemical vapor deposition method, however, this high-temperature deposition process will affect the already patterned core layer fine lines, resulting in line edge roughness (LER) problem. Therefore, there is a need in this industry to provide an improved self-aligned double patterning process in order to overcome the above-mentioned problems.

### SUMMARY OF THE INVENTION

According to one aspect of the invention, a semiconductor fabrication method is disclosed. A substrate is provided. A base layer, a hard mask layer, and a core layer are formed on the substrate. A resist pattern is formed on the core layer. A first anisotropic dry etching process is performed to transfer the resist pattern into the core layer, thereby forming a core pattern. The core pattern is subjected to a post-clean process. After the post-clean process, a spacer layer is deposited on the core pattern. A second anisotropic dry etching process is then performed to etch the spacer layer, thereby forming a spacer pattern on each sidewall of the core pattern. The core pattern is removed. A third anisotropic dry etching process is performed to transfer the spacer pattern into the hard mask layer and the base layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 show the main steps of a self-aligned double patterning (SADP) process in cross-sectional views according to one embodiment of the present invention.

FIG. 6 illustrates a flowchart of the present invention self-aligned double patterning process.

### DETAILED DESCRIPTION

In the following detailed description of the invention, reference is made to the accompanying drawings which form a part hereof, and in which is shown, by way of illustration, specific embodiments in which the invention may be practiced. These embodiments are described in sufficient detail to enable those skilled in the art to practice the invention. Other embodiments may be utilized and structural, logical, and electrical changes may be made without departing from the scope of the present invention. The following detailed description is, therefore, not to be taken in a limiting sense, and the scope of the present invention is defined by the appended claims.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

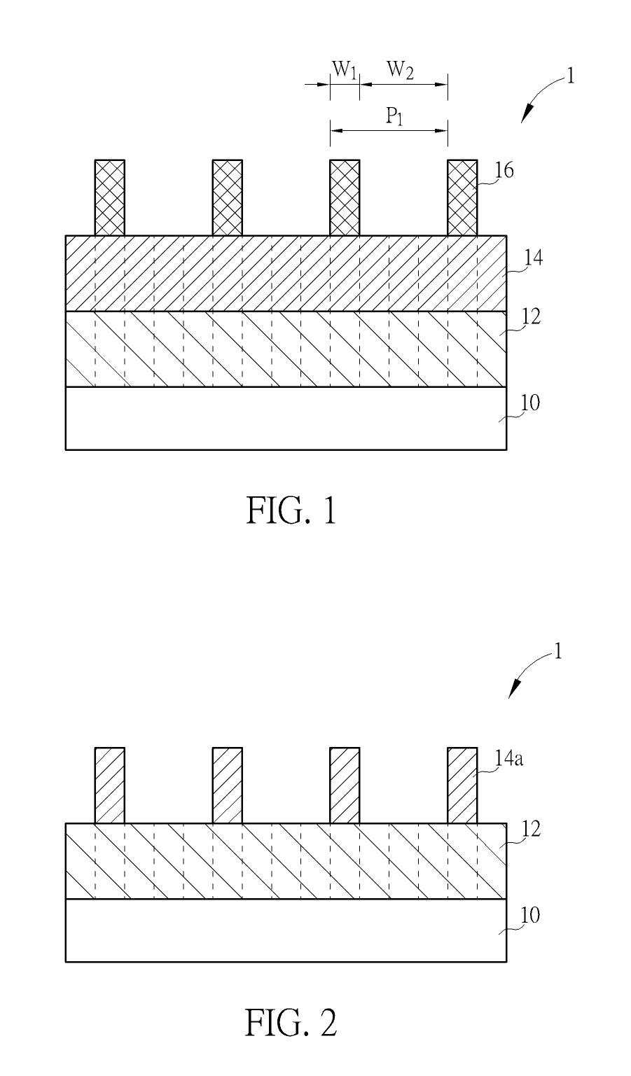

FIG. 1 to FIG. 5 show the main steps of a self-aligned double patterning (SADP) process in cross-sectional views according to one embodiment of the present invention. First, as shown in FIG. 1, a semiconductor substrate 1 is provided. The semiconductor substrate 1 has thereon a base layer 10, a hard mask layer 12 on the base layer 10, and a core layer 14 on the hard mask layer 12. Subsequently, a photoresist pattern or resist pattern 16 is formed on the core layer 14. According to the embodiment of the invention, the pattern on the mask will be reduced at least to half the original pitch and transferred to the base layer 10, so base layer 10 can be referred to as the target layer. It should be understood by those skilled in the art, although FIG. 1 to FIG. 5 show a self-aligned double patterning process, but the present invention can also be applied in a self-aligned multiple pattern process, for example, self-aligned triple patterning process or self-aligned quadruple patterning process and so on.

According to the embodiment of the invention, the photoresist pattern 16 may be comprised of parallel straight line-shaped patterns, but not limited thereto. It should be understood that other patterns may be employed. According to the embodiment of the invention, the photoresist pattern 16 may have a line width w1 a space w2 between two adjacent line patterns. The pitch P1 is the sum of w1 and w2 (P1=w1+w2). According to the embodiment of the invention, the space w2 of the photoresist pattern 16 is preferably greater than the line width w1, for example, w2:w1=3:1. According to the embodiment of the invention, for example, the photoresist pattern 16 maybe any suitable photoresist materials used in 193 nm lithography system (ArF photoresist). Of course, in other cases, the photoresist pattern 16 may be photoresist materials used in other lithography systems, for example, 248 nm (KrF) lithography system, e-beam system, and so on. In this embodiment, the photoresist pattern 16 maybe a positive type photoresist, that is, the regions exposed to light during exposure process will be removed by developing solution, while leaving the unexposed regions intact. However, in other cases, the photoresist pattern 16 may be a negative type photoresist. Further, in some embodiments, an anti-reflection layer (not shown) may be disposed between the photoresist pattern 16 and the core layer 14.

According to the embodiment of the invention, the base layer 10 may comprise a silicon substrate, a polysilicon layer, a metal layer, a dielectric layer, etc., depending on the desired circuit or component to be formed in the base layer 10. For example, when a damascened copper line is formed, the base layer 10 may be a dielectric layer or low dielectric constant (k) material layer. A trench-type pattern structure will be formed in the base layer 10 in this case. In a case that a buried gate, transistor, or buried word line/bit line is to be formed, the base layer 10 may be silicon substrate.

According to the embodiment of the invention, the hard mask layer 12 may be a polycrystalline silicon (polysilicon) layer, silicon nitride layer, and soon. According to the embodiment of the invention, the hard mask layer 12 maybe a single layer structure or a multi-layer structure. According to the embodiment of the invention, the core layer 14 is an amorphous carbon layer or other porous advanced patterning film (APF) materials. In this embodiment, the hard mask material layer 12 is composed of a single layer structure composed of polysilicon, and the core layer 14 is formed of a single material as a single layer structure composed of amorphous carbon and is formed directly on the hard mask layer 12. In other words, in this embodiment, the hard mask layer 12 is in direct contact with the core layer 14, and no other material layer is interposed between the hard mask layer 12 and the core layer 14.

As shown in FIG. 2, after forming the photoresist pattern 16, a first anisotropic dry etching process is performed using the photoresist pattern 16 as an etching resist layer, to remove the core layer 14 not covered by the photoresist pattern 16, thereby forming the core layer pattern 14a. At this point, the photoresist pattern 16 has been transferred to the core layer 14. Then, a pattern trimming process may be carried out. For example, the core layer pattern 14a may be in contact with oxygen plasma, 14a to further shrink line width of the core layer pattern to the desired size. In addition to the oxygen plasma as described above, the pattern trimming process may comprise other approaches, for example, N2/H2 gas, He/H2 gas, oxygen plasma incorporated with CF4 gas, but not limited thereto.

According to the embodiment of the invention, subsequently, a post-clean process is carried out to remove the polymer residuals generated during the first anisotropic dry etching process. According to the embodiment of the invention, the above-described post-clean process is performed by subjecting the surfaces of the semiconductor substrate 1 (i.e., the surface of the core layer pattern 14a and the partial surface of the hard mask layer 12) to a predetermined cleaning solution at a predetermined temperature for a predetermined time period. According to the embodiment of the invention, the cleaning solution used in the above-described post-clean process may include, but are not limited to, SPM cleaning solution (sulfuric acid mixed with hydrogen peroxide to a certain percentage, such as sulfuric acid to hydrogen peroxide at volume ratio 5:1), APM cleaning solution (ammonia, hydrogen peroxide, and pure water mixed at a certain ratio, diluted APM cleaning solution, dilute hydrofluoric acid (DHF) solution, isopropyl alcohol (IPA), diluted sulfuric acid/hydrogen peroxide (also known as DSP) solution (sulfuric acid, hydrogen peroxide, and pure water mixed at a certain ratio), DSP+ (DSP solution added with HF to a predetermined concentration within 10 wt %). According to the embodiment of the invention, the predetermined temperature may range from room temperature to 165° C., preferably, from room temperature to 65° C., depending on the type of the cleaning solution used. According to the embodiment of the invention, the predetermined contact time period may range from 20 seconds to 3 minutes, depending on the type of cleaning solution used. According to the embodiment of the invention, said predetermined contact time period is less than or equal to 3 minutes.

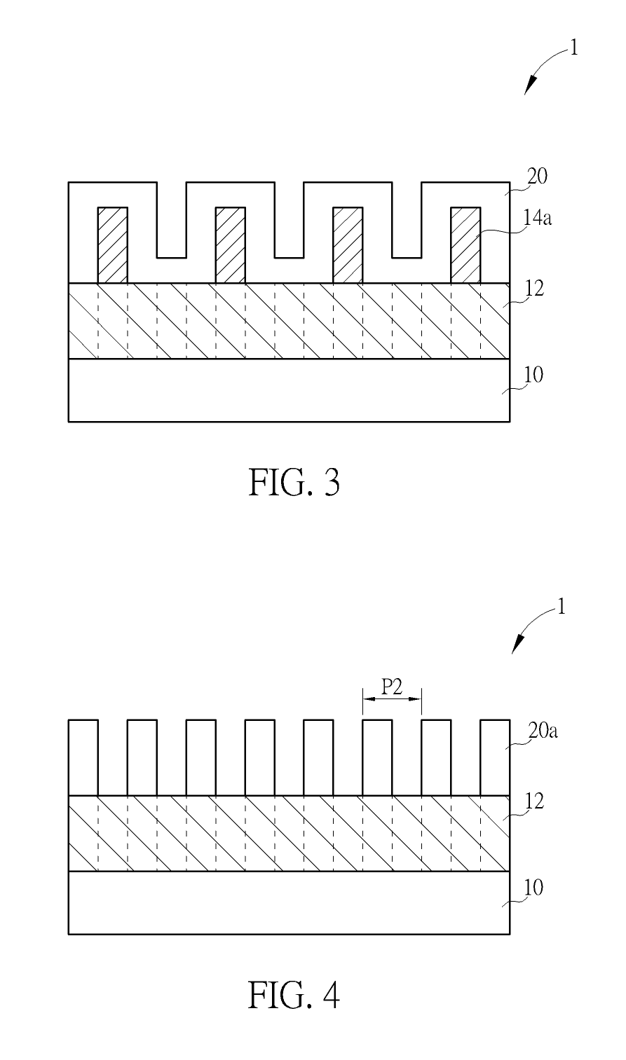

As shown in FIG. 3, after the cleaning process, a deposition process, e.g., chemical vapor deposition (CVD) or atomic layer deposition (ALD) is performed. A conformal spacer layer 20 is formed on the surface the core layer pattern 14a, and the exposed surface of the hard mask layer 12. According to the embodiment of the invention, the spacer layer 20 comprises silicon oxide or silicon nitride, and has a uniform thickness, roughly equal to the line width of the core layer pattern 14a. According to the embodiment of the invention, the above-described deposition process can be deposited at temperatures greater than or equal to 400° C., thereby forming a dense spacer layer 20. According to the embodiment of the invention, the dense spacer layer 20 may provide high etch selectivity with respect to the core layer pattern 14a to greatly enhance the process window.

As shown in FIG. 4, after the spacer layer 20 is deposited, a second anisotropic dry etching process is then carried out, to thereby form a spacer pattern 20a on the opposite side walls of the core layer pattern 14a. Subsequently, the core layer pattern 14a is selectively removed, leaving only the spacer pattern 20a. At this point, after the pattern transferred to the spacer layer 20, the pitch P2 is half the pitch P1 of the original photoresist pattern 16.

As shown in FIG. 5, using the spacer pattern 20a as an etching resist layer, a third anisotropic dry etching process is performed to remove the hard mask layer 12 not covered by the spacer pattern 20a, thereby transferring the spacer pattern 20a to the hard mask layer 12 to form a hard mask pattern 12a. Subsequently, a fourth anisotropic dry etching process is performed, using the hard mask pattern 12a as an etching resist layer, thereby transferring the hard mask pattern 12a to the base layer 10, whereby the fabrication of the device or the wiring pattern is complete.

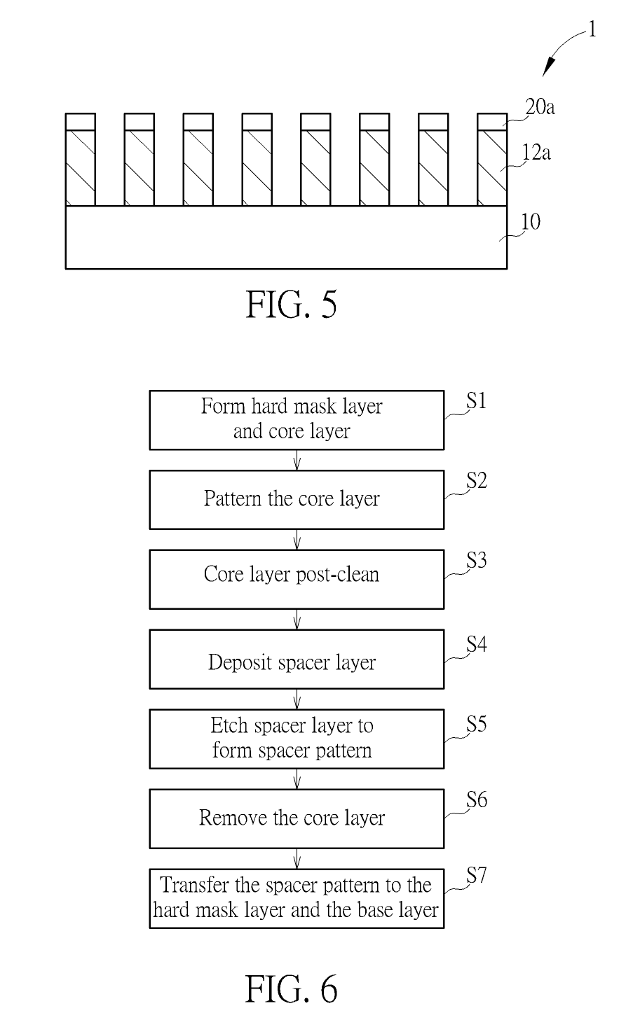

FIG. 6 illustrates a flowchart of the present invention self-aligned double patterning process. As shown in FIG. 6, first in Step S1: the hard mask layer 12 and the core layer 14 are formed on the base layer 10 of substrate 1; Step S2: a core layer 14 is patterned; Step S3: the core layer post-clean process is performed; Step S4: the spacer layer 20 is deposited; Step S5: the spacer layer 20 is etched to form the spacer pattern 20a; Step S6: the remaining core layer 14 is removed; and Step S7: the spacer pattern 20a is transferred to the hard mask layer 12 and base layer 10.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor fabrication method, comprising:
providing a substrate having thereon a base layer, a hard mask layer on the base layer, and a core layer on the hard mask layer;
forming a resist pattern on the core layer;
performing a first anisotropic dry etching process to transfer the resist pattern into the core layer, thereby forming a core pattern;
after forming the core pattern, performing a pattern trimming process to trim the core pattern;
subjecting the core pattern to a post-clean process to remove polymeric residuals generated during the first anisotropic dry etching process;
after the post-clean process, depositing a spacer layer on the core pattern;
performing a second anisotropic dry etching process to etch the spacer layer, thereby forming a spacer pattern on each sidewall of the core pattern;
removing the core pattern; and
performing a third anisotropic dry etching process to transfer the spacer pattern into the hard mask layer.

2. The semiconductor fabrication method according to claim 1 wherein the base layer comprises a silicon substrate, a polysilicon layer, a metal layer or a dielectric layer.

3. The semiconductor fabrication method according to claim 1 wherein the hard mask layer comprises polysilicon or silicon nitride.

4. The semiconductor fabrication method according to claim 1 wherein the core layer comprises an amorphous carbon layer.

5. The semiconductor fabrication method according to claim 1 wherein the post clean process includes making the core pattern contact with a pre-determined cleaning solution at a pre-determined temperature for a pre-determined time period.

6. The semiconductor fabrication method according to claim 5 wherein the pre-determined cleaning solution comprises SPM solution, APM solution, dilute APM solution, dilute hydrofluoric acid, isopropyl alcohol, dilute sulfuric acid and hydrogen peroxide mixture (DSP), or a dilute mixture of sulfuric acid, hydrogen peroxide and hydrofluoric acid (DSP+).

7. The semiconductor fabrication method according to claim 5 wherein the pre-determined temperature ranges between room temperature and 165° C.

8. The semiconductor fabrication method according to claim 5 wherein the pre-determined time period ranges between 20 seconds and 3 minutes.

9. (canceled)

10. The semiconductor fabrication method according to claim 1 wherein the spacer layer is deposited at a deposition temperature that is equal to or greater than 400° C.
